(19) United States
(12) Patent Application Publication
(10) Pub. No.: US 2022/0121122 A1
(43) Pub. Date: Apr. 21, 2022

(54) IN-SITU SYNTHESIS AND DEPOSITION OF HIGH ENTROPY ALLOY AND MULTI METAL OXIDE NANO/MICRO PARTICLES BY FEMTOSECOND LASER DIRECT WRITING

(71) Applicant: PANASONIC FACTORY SOLUTIONS ASIA PACIFIC, Singapore (SG)

(72) Inventors: Chidanand HEGDE, Singapore (SG); Chin Huat Joel LIM, Singapore (SG); Hua LI, Singapore (SG)

(21) Appl. No.: 17/502,539

(22) Filed: Oct. 15, 2021

Related U.S. Application Data
(60) Provisional application No. 63/092,710, filed on Oct. 16, 2020.

(51) Int. Cl. G03F 7/20; G03F 7/004

(52) U.S. Cl. CPC G03F 7/2053; G03F 7/0043; G03F 7/70383

(57) ABSTRACT

A method for synthesizing and simultaneously depositing and coating one or more layers of mixed metals to obtain one or more layers of high entropy alloys (HEAs) includes depositing a first metal precursor ink and drying the first metal precursor ink to obtain a first precursor film layer, applying a laser-direct writing (LDW) with pulsed laser source to the first precursor film layer to obtain a first layer of HEA, and rinsing the first layer of HEA with water to remove un-sintered precursor film to obtain one or more layers of HEAs. The first layer of HEA has a first metal corresponding to the first metal precursor. The one or more layers of HEAs includes a predetermined pattern of one or more layers, and the one or more layers may have a single metal or multiple metals.

### CROSS-REFERENCE TO RELATED APPLICATION

This application claims priority to U.S. Provisional Application No. 63/092,710, filed by PANASONIC FACTORY SOLUTIONS ASIA PACIFIC, on Oct. 16, 2020, and entitled IN-SITU SYNTHESIS AND DEPOSITION OF HIGH ENTROPY ALLOY AND MULTI METAL OXIDE NANO/MICRO PARTICLES BY FEMTOSECOND LASER DIRECT WRITING.

### TECHNICAL FIELD

The present disclosure relates to the field of synthesis of a transition metal compound, and in particular relates to synthesis and deposition of high entropy alloy and multi metal oxide nano/micro particles by femtosecond laser direct writing (FsLDW).

### BACKGROUND

Transition metal compounds such as alloys, oxides, hydroxides, sulfides, selenides, etc. are ubiquitous materials for energy storage, energy conversion, metrology, sensing, and monitoring. In the conventional processes, these compounds are synthesized through a variety of routes such as solvothermal processes, arc melting, chemical vapor deposition, ball milling, and solid-state reaction. However, these processes usually require a highly controllable environment and synthesis of these compounds involve the use of solvents and chemicals that are unsafe to the environment. Further, the assembly of the electrochemical devices using these compounds demands the use of binders to form a slurry, whereas the presence of binder and lack of close electrical contact between the active materials and the electrode results in higher charge transfer resistance for electrochemical applications. Other approaches such as growing the active material directly on conductive substrates such as metal forms, carbon cloth, or carbon paper for synthesizing binder-free electrodes may limit the choice of conductive substrates because the conductive substrates need to be inert.

Therefore, a new approach to produce transition metal compounds more efficiently is in demand. A laser-direct writing (LDW) method for producing micrometer resolution devices and systems can be simple, design-flexible, and cost-effective. Such an approach allows the synthesis process to be versatile and the alloys of various metals can be synthesized by a simple change in the composition of the ink. The synthesis process can synthesize alloys comprising up to 5 metals such as Ni, Co, Cu, Fe and Cr.

### SUMMARY

According to one aspect of the present disclosure, a method for synthesizing and simultaneously depositing and coating one or more layers of mixed metals to obtain one or more layers of high entropy alloys (HEAs) is provided. The method includes depositing a first metal precursor ink and drying the first metal precursor ink to obtain a first precursor film layer, applying a laser-direct writing (LDW) with pulsed laser source to the first precursor film layer to obtain a first layer of HEA, and rinsing the first layer of HEA with water to remove un-sintered precursor film to obtain one or more layers of HEAs. The first layer of HEA has a first metal corresponding to the first metal precursor. The one or more layers of HEAs includes a predetermined pattern of one or more layers, and the one or more layers may have a single metal or multiple metals.

According to another aspect of the present disclosure, a material having one or more high entropy alloys (HEAs) is provided. The material includes one or more layers of HEAs. The one or more layers of HEAs includes a predetermined pattern of one or more layers, and the one or more layers has a single metal or multiple metals. For each layer of HEA, a first metal precursor ink is deposited and dried for obtaining a first precursor film layer, a laser-direct writing (LDW) with pulsed laser source is applied to the first precursor film layer to obtain a first layer of HEA, the first layer of HEA having a first metal corresponding to the first metal precursor, and the first layer of HEA is rinsed with water to remove un-sintered precursor film to obtain a first layer of HEA.

### BRIEF DESCRIPTION OF THE DRAWINGS

A more particular description of the embodiments briefly described above will be rendered by reference to specific embodiments that are illustrated in the appended drawings. Understanding that these drawings depict only some embodiments and are not therefore to be considered to limit the scope, the embodiments will be described and explained with additional specificity and detail through the use of the drawings below.

FIG. 1 illustrates a flowchart for synthesizing a multi-material layers of high entropy alloys according to some embodiments of the present disclosure;

FIG. 2 shows field emission scanning electron microscopy (FESEM) images of femtosecond laser direct writing (FsLDW) pattern on (a) stainless steel foil without ink; and (b) stainless steel foil with ink according to some embodiments of the present disclosure;

FIG. 3 shows FESEM images of FsLDW patterns of Cu for different salt concentrations from 0.01 M to 0.5 M (a-e) and FESEM images of FsLDW patterns of Cu for different polymer concentration from 0.2 mg/ml to 1 mg/ml (f-j) according to some embodiments of the present disclosure;

FIG. 4 shows FESEM images of FsLDW patterns corresponding to various laser power from 200 mW to 700 mW according to some embodiments of the present disclosure;

FIG. 5 shows FESEM images of FsLDW patterns corresponding to various laser scan speed form 10 mm/s to 100 mm/s according to some embodiments of the present disclosure;

FIG. 6 shows X-ray diffraction (XRD) patterns of Cu synthesized by FsLDW corresponding to (a) different laser powers; and (b) different laser writing speeds according to some embodiments of the present disclosure;

FIG. 7 shows XRD patterns of (a) NiO, (b) CoO, (c) CuO/Cu₂O, (d) ZnO, (e) Cr₂O₃, (f) Fe₂O₃/Fe₃O₄, (g) SnO₂, (h) MnO/Mn₃O₄, and (i) Al₂O₃ synthesized by FsLDW according to some embodiments of the present disclosure;

FIG. 8 shows XRD spectra of (a) CoNi oxide, (b) NiMn oxide, (c) CoCr oxide, (d) CuCo oxide, (e) CuFe oxide, (f) CrFe oxide, (g) NiFe oxide, (h) NiCr oxide, (i) FeCo oxide, (j) NiCu_{0.1} oxide, (k) ZnCu_{0.1} oxide, and (l) Indium tin oxide synthesized by FsLDW according to some embodiments of the present disclosure;

FIG. 9 shows XRD spectra of (a) NiFeCr oxide, (b) NiCoCu oxide, (c) NiCoCr oxide, (d) CoFeCr oxide, (e) NiCoFe oxide, (f) NiCuCoCr oxide, (g) NiCoCuFe oxide, (h) Ni_{0.5}Co_{0.5}Fe₂Cr_{0.5} oxide, (i) Co_{0.5}Cu_{0.5}Fe₂Cr_{0.5} oxide, (j) Ni_{0.5}Cu_{0.5}Fe₂Cr_{0.5} oxide, (k) NiCoCuFeCr oxide, and (l) Ni_{0.25}Co_{0.25}Cu_{0.25}Cr_{0.25}Fe₂ oxide synthesized by FsLDW according to some embodiments of the present disclosure;

FIG. 10 shows FESEM energy-dispersive X-ray spectroscopy (EDS) elemental mapping and corresponding EDS spectra for femtosecond laser synthesized (a) NiCo oxide, (b) NiMn oxide, (c) CoCr oxide, (d) CoCu oxide, (e) FeCu oxide, and (f) FeCr oxide according to some embodiments of the present disclosure;

FIG. 11 shows FESEM EDS elemental mapping and corresponding EDS spectra for femtosecond laser synthesized (a) NiFe oxide, (b) NiCr oxide, (c) CoFe oxide, (d) NiCu_{0.1} oxide, (e) ZnCu_{0.1} oxide, and (f) NiCoCu oxide according to some embodiments of the present disclosure;

FIG. 12 shows FESEM EDS elemental mapping and corresponding EDS spectra for femtosecond laser synthesized (a) NiCoCr oxide, (b) CoFeCr oxide, and (c) NiCoFe oxide according to some embodiments of the present disclosure;

FIG. 13 shows FESEM EDS elemental mapping and corresponding EDS spectra for femtosecond laser synthesized (a) NiCoCuCr oxide, (b) NiCoCuFe oxide, (c) NiCoFeCr oxide, (d) CoCuFeCr oxide, (e) Ni_{0.5}Cu_{0.5}Fe₂Cr_{0.5} oxide, and (f) NiCoCuFeCr oxide according to some embodiments of the present disclosure;

FIG. 14 shows XRD spectra of (a) Pt, (b) Au, (c) Ag, (d) Cu, (e) Ni, (f) Co, (g) In, (h) NiCo, (i) NiCu, (j) NiFe, (k) CoFe, (l) CoCu synthesized by FsLDW according to some embodiments of the present disclosure;

FIG. 15 shows XRD spectra of (a) FeCu, (b) NiCoCu, (c) NiCoCr, (d) CoFeCu, (e) NiCoFe, (f) NiCuCr, (g) NiFeCuCr, (h) NiCoFeCr, (i) NiCoCuFe, (j) NiCoCuCr, (k) CoCuFeCr, and (l) NiCoCuFeCr alloys synthesized by FsLDW according to some embodiments of the present disclosure;

FIG. 16 shows FESEM EDS elemental mapping and corresponding EDS spectra for femtosecond synthesized (a) NiCo, (b) NiCu, (c) NiFe, (d) CoFe, (e) CoCu, and (f) FeCu alloys according to some embodiments of the present disclosure;

FIG. 17 shows FESEM EDS elemental mapping and corresponding EDS spectra for femtosecond synthesized (a) NiCoCu, (b) NiCoCr, (c) CoFeCu, (d) NiCoFe, and (e) NiCuCr alloys according to some embodiments of the present disclosure;

FIG. 18 shows FESEM EDS elemental mapping and corresponding EDS spectra for femtosecond synthesized (a) NiFeCuCr, (b) NiCoFeCr, (c) NiCoCuFe, (d) NiCoCuCr, (e) CoCuFeCr, and (f) NiCoCuFeCr alloys according some embodiments of the present disclosure;

FIG. 19 illustrates (a) Comparison of OER activity of NiCoCuFeCr_{0.5} HEA alloy with NiFe alloy and pristine carbon fiber paper, and (b) corresponding Tafel slopes, and comparison of specific activity for hydrogen evolution of (c) femtosecond laser synthesized NiAg_{0.4} vs. NiAg_{0.4} 3DPNC synthesized by hydrothermal process, (d) femtosecond laser synthesized NiCu_{0.05}Fe_{0.025} vs. NiCu_{0.05}Fe_{0.025} PNW synthesized by hydrothermal process, (e) chronopotentiometry testing to investigate the stability of CFP at NiCoCuFeCr_{0.5} HEA at a constant current density of 10 mA cm′, and (f) comparison of specific activity of the catalysts synthesized by conventional processes against the femtosecond laser process at 0.1 mA cm⁻²_{(ECSA)} according to some embodiments of the present disclosure;

FIG. 20 shows (a) Concentric squares, (b) concentric circles of NiO fabricated by FsLDW, (c) micropatterning of logo of Nanyang Technological university by femtosecond laser and corresponding (d) EDS elemental mapping image, (e) Concentric circles of Ni, Cu and Ag patterned by femtosecond laser direct writing in 3 consecutive steps and the corresponding (f) EDS line scan spectra according to some embodiments of the present disclosure; and

FIG. 21 shows optical microscope images of fabricated patterns under various laser powers according to some embodiments of the present disclosure.

### DETAILED DESCRIPTION OF THE EMBODIMENTS

It will be readily understood that the components of the embodiments, as generally described and illustrated in the figures herein, may be arranged and designed in a wide variety of different configurations in addition to the described example embodiments. Thus, the following more detailed description of the example embodiments, as represented in the figures, is not intended to limit the scope of the embodiments, as claimed, but is merely representative of example embodiments.

The present disclosure provides a Laser-direct writing (LDW) method for producing micrometer-resolution device and system. Upon implementation of the LDW method disclosed by the present disclosure, a user can synthesize and simultaneously coat/deposit multi-metal oxides and high entropy alloy micro and nanoparticles using femtosecond laser direct writing (FsLDW).

LDW may support a broad range of substrate materials and provide higher throughput and scalable patterning compared to other methods. For example, LDW can process different types of materials depending on the wavelength of the laser source used. In this regard, continuous-wave CO₂ lasers may be applied to LDW, and short-pulse lasers may also be used for LDW.

The advantages of the femtosecond laser direct process over the conventional method of synthesis include a binder-free environment, rapidness, adoption of aqueous base ink, low solvent consumption, single step process being versatile for variety of metal oxides and alloys, possibility to synthesize on variety of substrates, and room temperature at an open atmosphere for synthesis, etc. In the conventional process, nanoparticles synthesized through variety of methods such as ball milling, hydrothermal process, solid state reaction, solvothermal process, arc melting, etc. The process is then followed by washing and drying of the powder and thermal annealing in a furnace. The thermal annealing is conducted in the present of inert gases such as Ar/N₂ or reducing atmospheres such as H₂/CO. The catalyst in the powder form can be later mixed with a conductive filler and a binder dispersed in isopropyl alcohol to obtain a catalyst slurry. The conductive filler may be, for example, super P carbon, and binders may be, for example, Nafion. The slurry is coated on a conductive substrate such as carbon fiber paper (CFP), carbon cloth, or metal foils and dried to obtain an electrode. The electrode may be used for energy storage, catalysis, or sensing. However, the whole fabrication process involves multiple steps and is time-consuming. Often, the above processes must be carried out at high temperature and pressure and require the use of a large quantity of solvents.

In contrast, the FsLDW according to the present disclosure is a single step rapid process. According to various embodiments of the present disclosure, the process employs aqueous based ink, with low usage of water and minute concentrations of binder. The process may be a cold process, and conducted at room temperature such that the substrate remains at the room temperature during and after the laser irradiation. Further, with suitable tuning of the composition of the ink and the additives, the final products of the synthesis are formed. The process may be carried out in an open atmosphere without the presence of any gas such as Ar, N₂, or H₂.

In one implementation, concentric circular patterns comprising Ni, Cu, and Ag patterns each with a thickness of 100 μm and a linear spacing of 100 μm can be synthesized. According to some embodiments, optimization of laser power, laser scan speed, and concentration of metal salts and concentration of polymer for the precursor ink can be important to the synthesis process. Through the process, oxides and metal alloys including, for example, 10 metals may be synthesized. The effectiveness and potency of this process can be proved by the synthesized products. The synthesized products may consist of nanoparticles of 20 nm-100 nm dimensions or microparticles of up to 10 μm. The synthesized products can display good bonding with the substrate.

The above-mentioned process can be used on a wide variety of substrates, for example, glass, metal foils, carbon fiber paper, and so forth, which facilitates easy fabrication routes for electrochemical devices. According to the embodiments of the present disclosure, the X-ray diffraction (XRD) patterns confirm the formation of expected compounds which is further supported by the XPS and TEM results. Furthermore, the synthesized materials do not require any post-processing and can be directly used for any desired application. In one implementation, the NiCoCuFeCr_{0.5} high entropy alloy synthesized by FsLDW exhibited excellent activity for oxygen evolution in 1 M KOH solution with low overpotential of 213 mV at 10 mA cm′ and excellent stability for 50 hours when operated at constant current density of 10 mA cm′. Therefore, the use of this process for one-step fabrication of micro-supercapacitors, batteries, and sensors paves way for rapid and cost-effective fabrication of these electrochemical devices.

According to the embodiments of the present disclosure, a FsLDW system can be achieved by the following procedure. A 25 μL ink may be drop cast on a stainless-steel plate/glass slide and dried on an electric hotplate at 60° C. for 15 minutes. The ink formed a uniform film over the substrate. The fabrication and patterning of transition metal alloy compounds can be implemented through a self-built FsLDW platform, with an Yb-doped fiber laser (e.g., Amplitude Systèmes, Satsuma HP) as the pulsed laser source and a set of angle scanning Galvano mirror to support fast laser beam writing. Writing condition of repetition rate 500 kHz using ultraviolet (UV) femtosecond pulse laser at 343 nm with pulse duration of 220 fs may be implemented. The laser average power may be, for example, between 200 mW and 700 mW, and the laser writing speed may be, for example, between 10 mms⁻¹ and 100 mms⁻¹. The laser average power and the laser writing speed can be varied to achieve different properties of the FsLDW pattern.

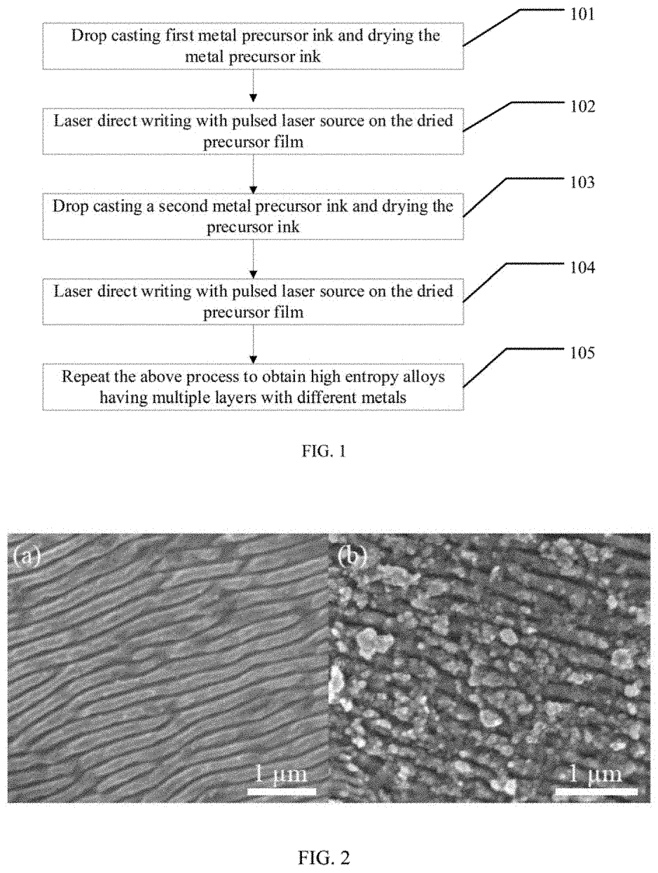

According to various embodiments of the present disclosure, the laser writing for multi-material fabrication can be conducted in three steps. FIG. 1 illustrates a flowchart for synthesizing multi-metal oxides and high entropy alloy micro and nanoparticles according to the embodiments of the present disclosure.

Step 101: Drop casting first metal precursor ink and drying the metal precursor ink.

In the first step, A thin film of the metal precursor ink may be formed. According to the embodiments of the present disclosure, the first metal may include both single composition and/or multi-metal composition.

Step 102: Laser direct writing with pulsed laser source on the dried precursor film.

In the second step, the precursor film may be processed by the pulsed laser to transform into metal or alloy and rinsed with water to remove the un-sintered precursor film if necessary. In some embodiments, the pulsed laser source may be an ultra-fast pulsed laser source.

Step 103: Drop casting a second metal precursor ink and drying the precursor ink.

In the third step, a thin film of the second metal precursor ink may be formed above the first layer.

Step 104: Laser direct writing with pulsed laser source on the dried precursor film

Like in the second step, the precursor film may be processed by the pulsed laser to transform into metal or alloy and rinsed with water to remove the un-sintered precursor film if necessary. In some embodiments, the pulsed laser source may be an ultra-fast pulsed laser source.

Step 105: Repeat the above process to obtain high entropy alloys having multiple layers with different metals.

Therefore, in some embodiments, there may be one high entropy alloy, when the first layer of HEA is the end product. In some other embodiments, there may be multiple layers of HEAs, and each layer may have metals different others. The one or more layers of HEAs may include a predetermined pattern with respect to the layers. The choice of sequence of first metal precursor ink, second metal precursor ink, third metal precursor ink, etc. can be carefully selected based on the chemical reactivity of the patterned metals or alloys. When metal precursor ink contains multiple metals, the formed pattern may be an alloy, whereas when a single metal is present, the formed pattern consists of single metal. The choice of metal precursor ink may determine the final product. There can be a single or multiple layers, hence the number of layers is not limited to three.

In some embodiments, XRD can be used for characterizing the properties of the synthesized multi-metal oxides and high entropy alloy micro and nanoparticles. In one implementation, XRD may be conducted on Shimadzu XRD-6000 X-ray diffractometer with CuK_{α} irradiation (e.g., λ=1.5406 Å) to identify phase of the synthesized samples. A morphology of samples may be characterized using field emission scanning electron microscopy (e.g., field emission scanning electron microscopy (FESEM), JEOL, 7600F) and transmission electron microscopy (TEM) (e.g., TEM, JEOL, JEM-2100F). For example, for the TEM testing, samples from the stainless steel foil may be scrapped and dispersed in ethanol and dropped on a TEM grid for testing. In one implementation, energy-dispersive X-ray spectroscopy (EDS), elemental mapping, and bright field scanning transmission electron microscopy (BF-STEM) may be performed by TEM (e.g., JEOL JEM 2100, at 200 kV) to obtain distribution of individual elements. The synthesized samples obtained according to the method for synthesizing multi-metal oxides and high entropy alloy micro and nanoparticles can be tested by inductive coupled plasma-optical emission spectroscopy results. In some embodiments, Fourier transformed infrared (FTIR) spectroscopy may be conducted to qualitatively assess polymer content remaining in the sintered sample. In some embodiments, UV-Vis spectroscopy may be carried out to determine the absorption pattern of the synthesized ink.

In some embodiments, electrochemical measurements can be done using Solartron analytical equipment (e.g., Model 1470E). In one implementation, tests for hydrogen evolution (HER) and oxygen evolution (OER) performance can be conducted in a typical three electrode system comprising Hg/HgO as a reference electrode, graphite electrode as a counter electrode in 1M KOH, and a laser patterned stainless steel foil/carbon fiber paper as an operating electrode. In some embodiments, the HER performance may be measured by linear sweep voltammetry (LSV) from −0.7 V to −1.7 V at 2 mV per second and the OER performance may be measured from 0 V to 1 V against Hg/HgO electrode. Further, the measured potential may be converted to potential against reversable hydrogen electrode (RHE) following an equation

E_{vsRHE}=E_{vsHg/Hgo}+0.098+0.059*pH

where E_{vsRHE} represents a potential against a reversable hydrogen electrode, and E_{vsHg/HgO} represents a measured potential for OER against a Hg/HgO electrode.

The durability of catalyst can be tested by chronoamperometry test by applying a constant current of 10 mA cm⁻² for 50 hours, and the voltage may be measured during the process.

In some embodiments, CV scans may be carried out from 0.3 V to 0.4 V vs Hg/HgO reference electrode at various scan rates, for example, the scan rates may range from 5 mV/s to 60 mV/s. The difference in the current density, j_{anodic}−j_{cathodic}, may be plotted against the scan rate. The slope of the plot equals twice the double layer capacitance Cal. The electrochemical active surface area (ECSA) was calculated by dividing the Cal by specific capacitance (e.g., assumed to be 40 g cm⁻²). The ECSA normalized current may be obtained by dividing the current density corresponding to the geometric area by the calculated ECSA.

Therefore, a novel method of electrode fabrication using femtosecond laser can be implemented based on the above synthesis process. The ink for the FsLDW can be synthesized by mixing metal salt solution and the polymer. FIG. 2 (a) shows micro-patterns formed by LDW on a stainless-steel foil without ink, and FIG. 2 (b) shows the micro-patterns formed on the stainless-steel foil with ink. The micro-nanoparticles formed during the laser irradiation can be strongly bonded to the stainless-steel foil. The process is versatile and can be repeated on a variety of substrates such as glass, carbon fiber paper, Zn foil, Cu foil, Ni foil, etc.

FIG. 3 illustrates FESEM images of FsLDW patterns of Cu for different salt concentrations from 0.01 M to 0.5 M (a-e) and FESEM images of FsLDW patterns of Cu for different polymer concentration from 0.2 mg/ml to 1 mg/ml (f-j) according to some embodiments of the present disclosure. As shown in FIG. 3 (f-j), the nature of nano-microparticles during the laser writing process may not be significantly affected by the polymer concentration. However, the presence of polymer may not be suitable for electrochemical applications such as electrolysis, and thus lower polymer concentrations are implemented in electrochemical applications.

According to the embodiments of the present disclosure, salt concentration may have significant effect on quality of the patterns. As shown in FIGS. 3 (a-f), the FESEM images of the patterns can be shown for inks with varying salt concentration. For example, at low salt concentrations of 0.01M to 0.05 M, the amount of nano-microparticles are extremely low, and the SEM images show micropatterns similar to the bare SS foil. In contrast, well-bonded nano-micro particles are clearly shown when the salt concentration ranges from 0.1 M to 0.5 M. According to various embodiments of the present disclosure, a salt concentration of 0.5 M may be implemented for all types of inks. Therefore, higher mass loading of active materials may be implemented for electrochemical applications.

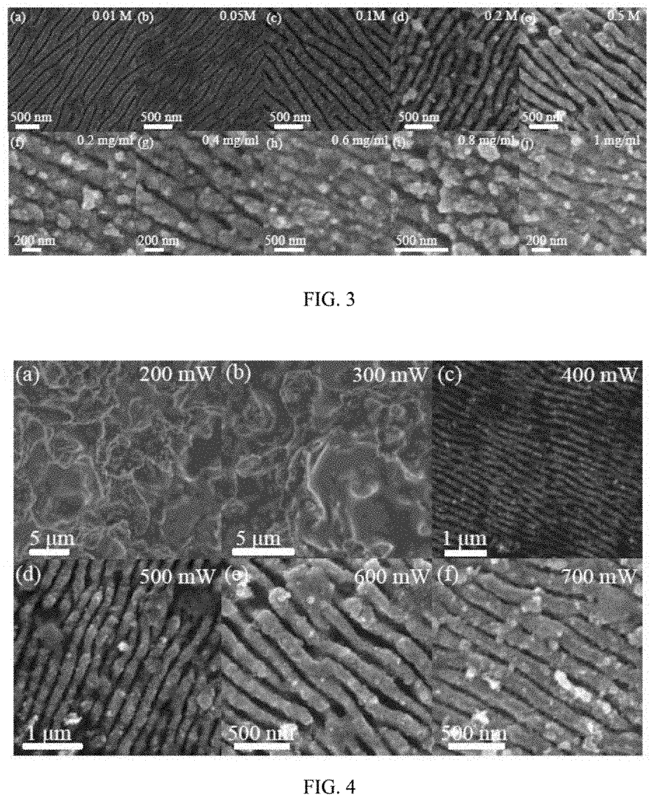

Furthermore, the laser power contributes greatly to the quality of the sintered samples. FIG. 4 illustrates FESEM images of FsLDW patterns corresponding to various laser power from 200 mW to 700 mW according to some embodiments of the present disclosure. As shown in FIG. 4 (a-c), at low laser average powers from 200 mW to 400 mW, the sample may not be sufficiently sintered, and the FESEM images may show darker regions between the sintered samples which indicates the unsintered polymer at lower powers. On the other hand, for example, at sufficiently high powers, for example, between 500 mW and 700 mW. In some embodiments, the laser power may be, for example, 600 mW. As shown in FIGS. 4 (d-f), the FESEM images show bright line patterns and clear images of nanoparticles. The FESEM images confirm the uniform sintering of the ink throughout the substrate.

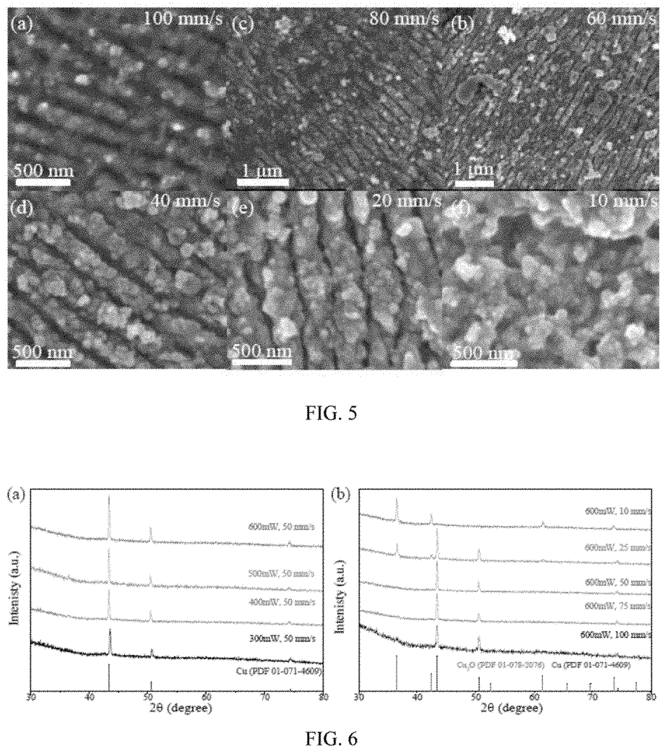

The laser scanning speed can also tune a total fluence of the laser beam on an area which in turn affects sintering characteristics. FIG. 5 illustrates FESEM images of FsLDW patterns corresponding to various laser scan speed form 10 mm/s to 100 mm/s according to some embodiments of the present disclosure. For example, as shown in FIG. 5 (a-f), by reducing the scan speed form 100 mm/s to 10 mm/s, the sintering of the sample can be enhanced, and the formation of micro-size line patterns can also be reduced. The micro size line patterns may be attributed to the fast scanning speed and direction. On the other hand, at low scan speed of 10 mm/s, as shown in FIG. 5 (f), there is no observed line patterns and only uniformly dispersed nanoparticles can be observed. According to various embodiments of the present disclosure, a scan speed of 40-60 mm/s can be sufficient to synthesize fully sintered nanoparticles to achieve the purpose of obtaining sufficient sintering samples as well as fast fabrication speeds for practical application in the industrial scales.

Furthermore, according to some embodiments of the present disclosure, phases of product formed under various laser writing speed and laser powers for Cu ink are provided. FIG. 6 illustrates X-ray diffraction (XRD) patterns of Cu synthesized by FsLDW corresponding to (a) different laser powers; and (b) different laser writing speeds according to some embodiments of the present disclosure. As shown in FIG. 6 (a), at scanning speed of 50 mm/s, Cu nanoparticle can be formed under a maximum power of 600 mW. Nonetheless, by reducing the scanning speed to below 50 mm/s, the Cu nanoparticles may be oxidized. Further, at the scanning speed of 25 mm/s, only the mixture of Cu and Cu₂O can be observed. Such phenomenon is due to accumulation of excessive energy at low scanning speeds. When the scanning speed is 10 mm/s, the product Cu₂O indicates a complete oxidation of Cu to Cu⁺. According to various embodiments of the present disclosure, a laser power of 600 mW and a scanning speed of 50 mm/s can be selected for synthesis of oxides and alloys.

The electrochemical applications often involve multi-element compounds which exhibit enhance functionality toward catalysis, energy storage, and sensing, etc. According to the embodiments of the present disclosure, a method for synthesizing multi-element compounds using FsLDW is provided.

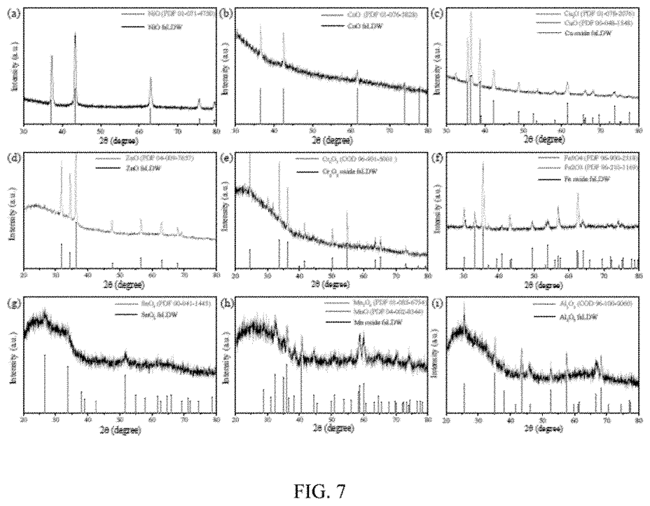

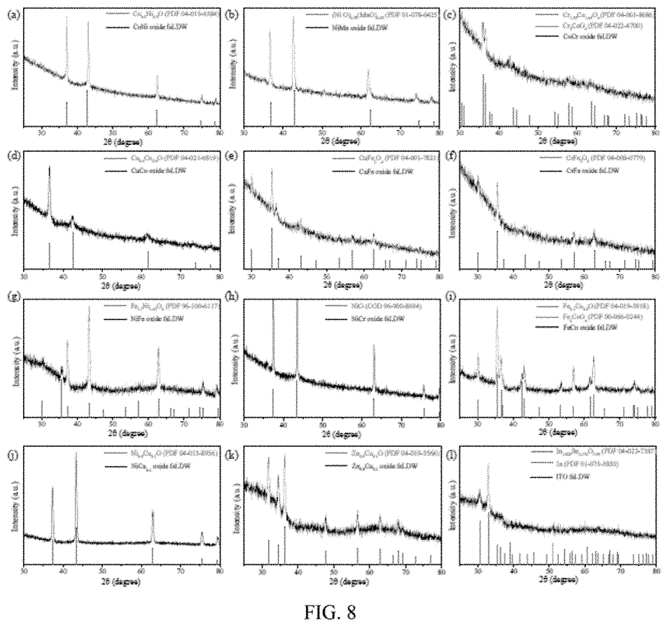

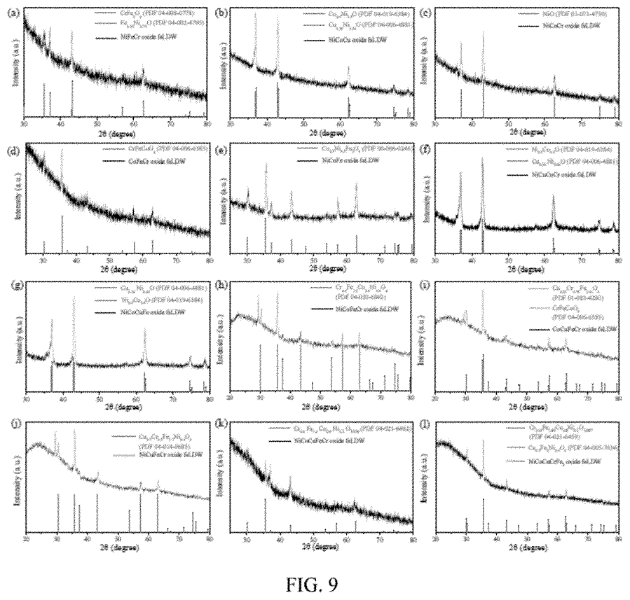

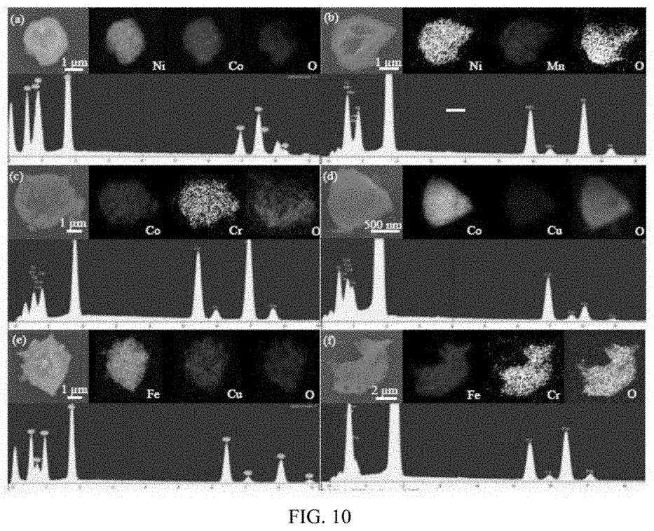

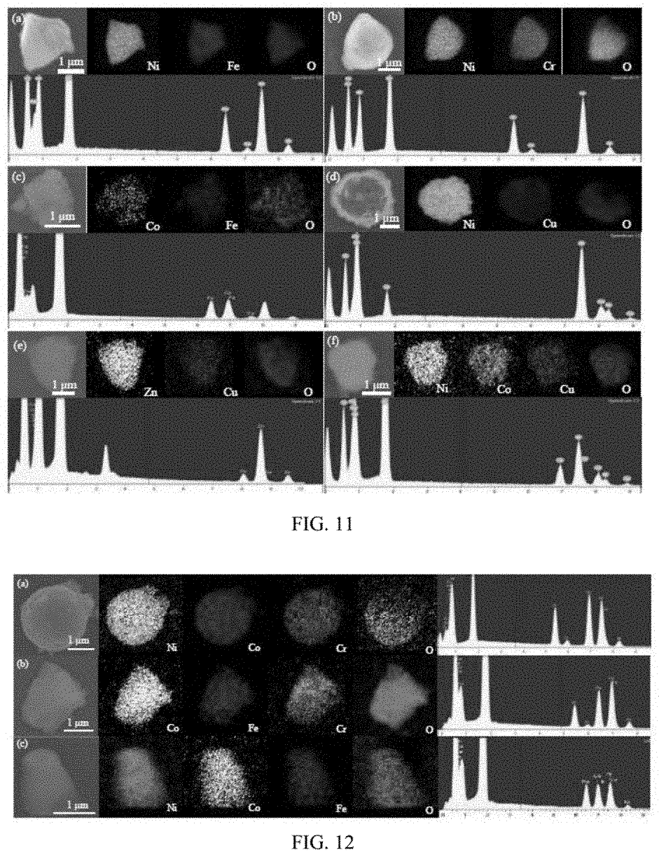

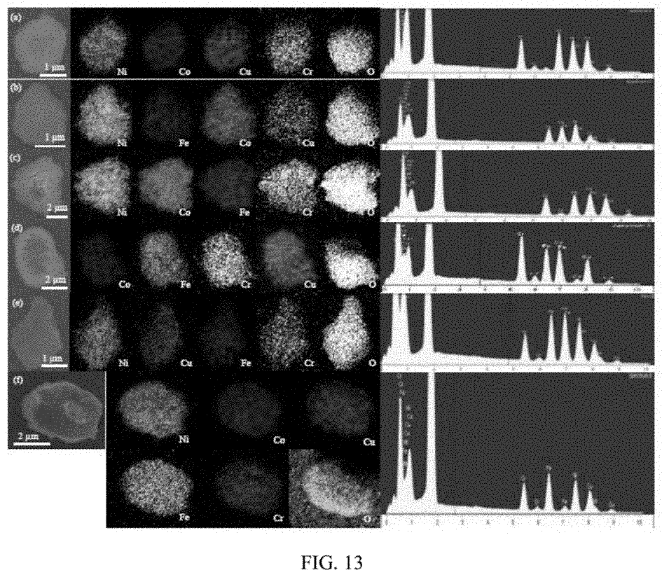

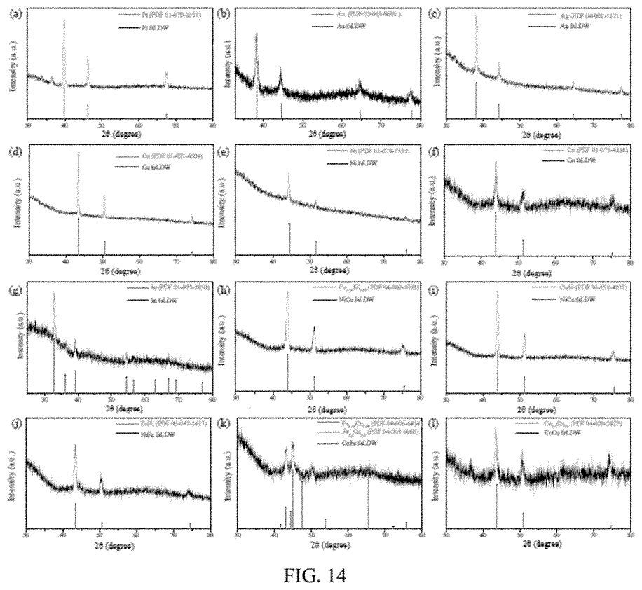

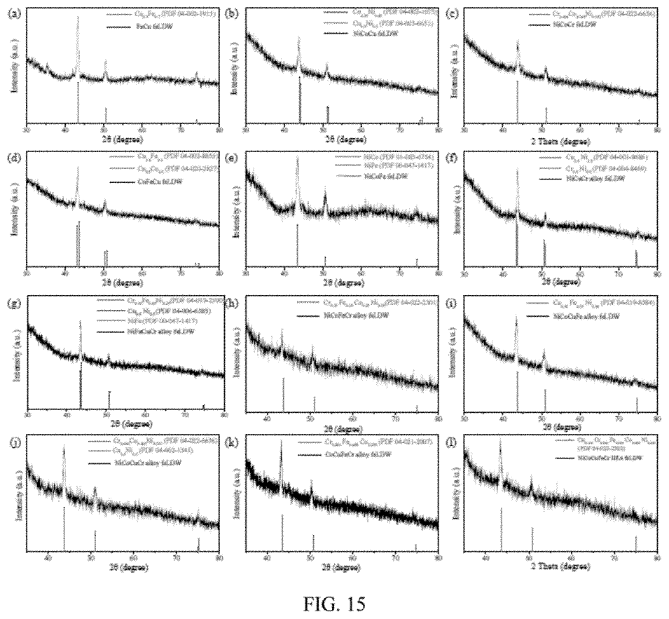

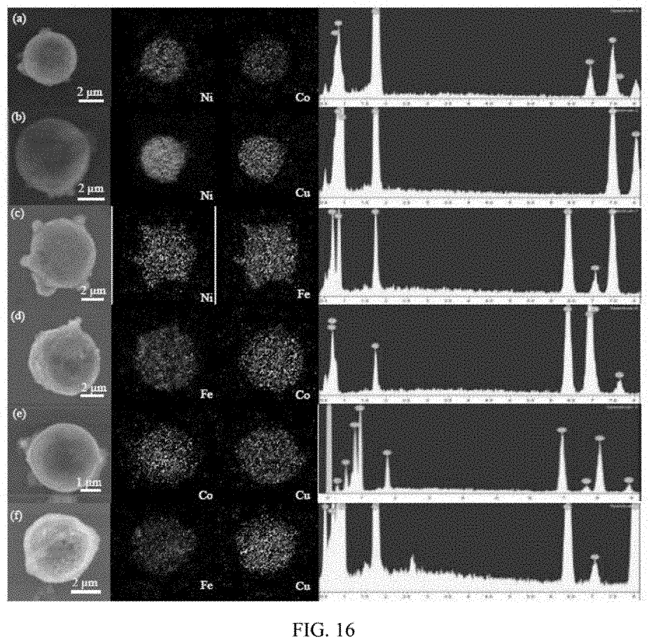

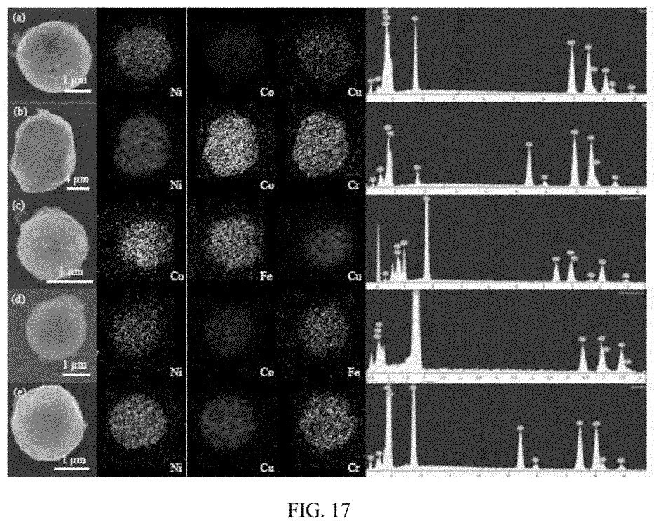

As shown in FIGS. 7, 8, and 9, the XRD spectra of the synthesized oxides have peaks. By changing composition of the ink, various multi-metal oxides can be synthesized using the above method. According to various embodiments of the present disclosure, metal oxides of Cu, Zn, Ni, Cr, Co, Fe, Sn, Al, Mn can be synthesized. Corresponding homogenous distribution of these metal oxides are illustrated in FIGS. 10, 11, 12, and 13. Thus, the formation of multi-metal oxides can be confirmed from XRD spectra and the EDX maps. Further, as shown in FIGS. 14 and 15, the XRD spectra of other metal alloys, for example, the XRD spectra of (a) Pt, (b) Au, (c) Ag, (d) Cu, (e) Ni, (f) Co, (g) In, (h) NiCo, (i) NiCu, (j) NiFe, (k) CoFe, (l) CoCu synthesized by FsLDW are also depicted in FIG. 14, and the XRD spectra of (a) FeCu, (b) NiCoCu, (c) NiCoCr, (d) CoFeCu, (e) NiCoFe, (f) NiCuCr, (g) NiFeCuCr, (h) NiCoFeCr, (i) NiCoCuFe, (j) NiCoCuCr, (k) CoCuFeCr, and (l) NiCoCuFeCr alloys synthesized by FsLDW are also depicted in FIG. 15.

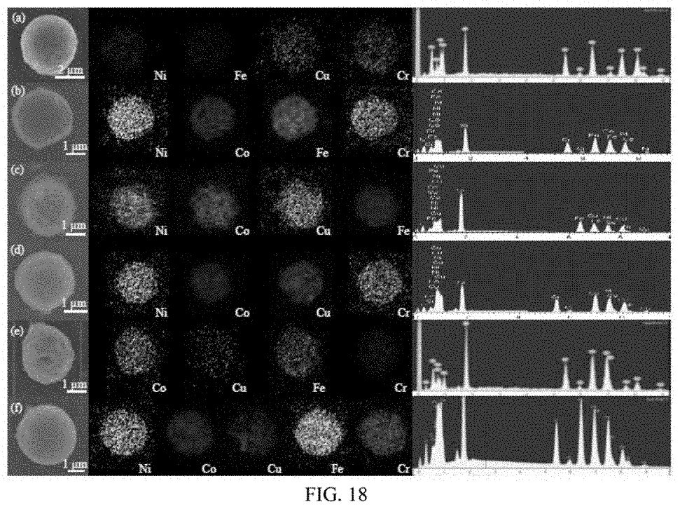

The above synthesis process is versatile and the alloys of various metals can be synthesized by a simple change in the composition of the ink. The synthesis process can synthesize alloys comprising up to 5 metals such as Ni, Co, Cu, Fe and Cr. Further, as depicted in FIGS. 16, 17, and 18, the EDX elemental mapping images show the homogeneous distribution of constitute elements thus confirming the formation of alloys. In the characterization using transmission electron microscopy (TEM), d-spacing of 0.210 nm is shown corresponding to plane of NiCoCuFeCr HEA. The STEM-EDX elemental mapping images also show the homogeneous distribution of constituent metals in NiCoCuFeCr alloy.

Table 1.1 shows the whole list of oxides and alloys that are synthesized according to the method for synthesizing metal oxides and alloys for fabrication of electrochemical devices disclosed by the present disclosure. It should be construed that the process is not limited to these compounds and other oxides and alloys can be synthesized using the same method. Therefore, other transition metals other than those included in Table 1.1 may also be fabricated according to the method disclosed by the present disclosure.

TABLE 1.1
List of Products which are synthesized through the
femtosecond laser direct writing (FsLDW) process

| Sl. | Product |
|---|---|
| No. | synthesized |
| 1. | Pt |
| 2. | Au |
| 3. | Ag |
| 4. | Cu |
| 5. | Ni |
| 6. | Co |
| 7. | Sn |
| 8. | NiCu |
| 9. | NiCo |
| 10. | NiFe |
| 11. | CuFe |
| 12. | CoFe |
| 13. | CoCu |
| 14. | NiCoCu |
| 15. | NiCoFe |
| 16. | CoFeCu |
| 17. | NiCoCr |
| 18. | NiCuCr |
| 19. | NiCoCuCr |
| 20. | NiCoCuFe |
| 21. | NiCoFeCr |
| 22. | NiCuFeCr |
| 23. | CoCuFeCr |
| 24. | NiCuFeCoCr |
| 25. | NiO |
| 26. | CoO |
| 27. | MnO/Mn₃O₄ |
| 28. | Fe3O4 |
| 29. | Cr2O3 |
| 30. | Al2O3 |
| 31. | ZnO |
| 32. | CuO, Cu₂O |
| 33. | In₂O₃ |
| 34. | NiFe oxide; |
| 35. | NiCo oxide |
| 36. | NiMn oxide |
| 37. | NiCr oxide |
| 38. | CoCu oxide |
| 39. | CoCr oxide |
| 40. | FeCr oxide |
| 41. | FeCu oxide |
| 42. | ITO |
| 43. | CoFe oxide |
| 44. | ZnCu_{0.1} oxide |
| 45. | NiCu_{0.1} oxide |
| 46. | CoFeCu oxide |
| 47. | NiCoCu oxide |
| 48. | NiCoCr oxide |
| 49. | NiFeCr oxide |
| 50. | CoFeCr oxide |
| 51. | NiCoFe oxide |
| 52. | NiCoFeCr oxide |
| 53. | NiCoCuFe oxide |
| 54. | NiCoCuCrO oxide |
| 55. | NiCuFeCr oxide |
| 56. | CoCuFeCr oxide |
| 57. | NiCoCuFeCr oxide |

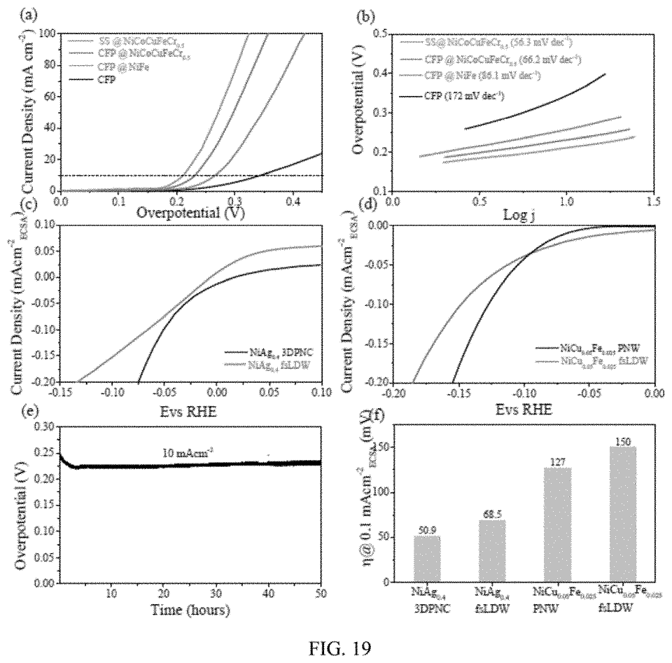

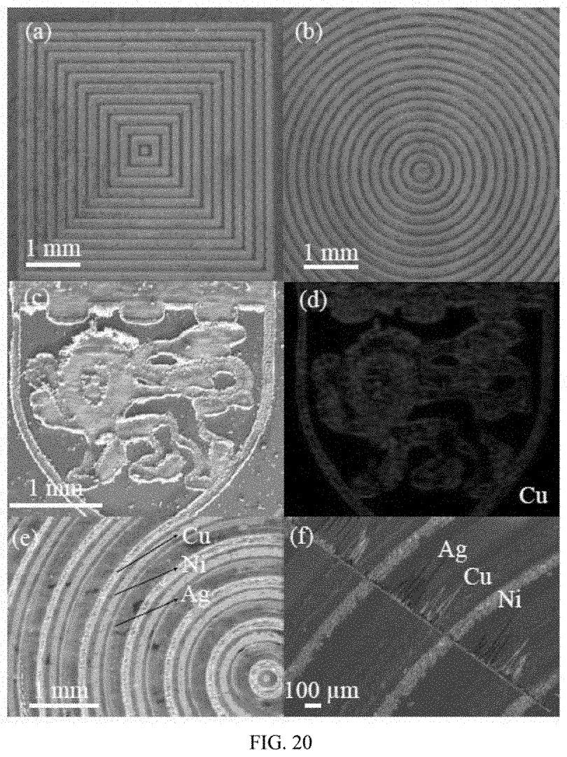

According to the embodiments of the present disclosure, catalysts may be employed for water splitting in the electrochemical applications. For example, catalysts may be applied for synthesis on stainless steel (SS) or carbon fiber paper (CFP). The stainless steel at NiCoCuFeCr_{0.5} HEA catalyst may be used as a catalyst for oxygen evolution reaction (OER). As shown in FIG. 19, the catalyst exhibits a low Tafel slope of 56.3 mV dec⁻¹, which indicates that a higher reaction kinetics for water splitting than other curve representing reaction without the catalysts in the same figure. Since stainless steel substrate is active for OER, the NiCoCuFeCr_{0.5} synthesized on carbon fiber paper (CFP) substrate are also tested. As shown in FIG. 19 (a), in one example, the CFP at NiCoCuFeCr_{0.5} exhibits excellent activity which corresponds to a lower overpotential of 232 mV at 10 mA cm′. In contrast, in another example, the bare carbon fiber paper may need an overpotential of 350 mV to achieve 10 mA cm′ which also corresponds to an excellent activity of the catalyst. Since Ni and Fe based alloys and oxides are known to exhibit high activity for OER, the activity for CFP at NiFe catalyst is tested to validate the activity of high entropy alloy of NiCoCuFeCr_{0.5}. In one example, as shown in FIG. 19 (a-b), the CFP at NiFe catalyst shows lesser activity compared to CFP at NiCoCuFeCr_{0.5} catalyst. Therefore, the high entropy alloy of Ni, Co, Cu, Fe, and Cr generates a catalyst with high OER activity.

The femtosecond laser fabricated electrodes can easily replace the electrodes fabricated through the conventional methods. Compared with specific activity of NiAg_{0.4} 3DPNC and NiCu_{0.05}Fe_{0.025}PNW catalysts against stainless steel at NiAg_{0.4} and stainless steel at NiCu_{0.05}Fe_{0.025} synthesized by femtosecond laser. As shown in FIG. 19 (c-d), the femtosecond laser synthesized catalysts show similar activity as of the conventionally synthesized catalysts. The conventional synthesized catalyst are tested on glass carbon electrode whereas the laser synthesized catalyst are tested on stainless steel foil which may contribute to the slight difference in the activity.

In addition, the activity of the catalyst by itself does not attract the commercial application. The long-term durability of the catalyst is an important aspect to consider. The durability by conducting chronopotentiometry test at 10 mA cm⁻² for 50 hours. As seen from FIG. 19, the catalyst exhibits excellent stability with no visible increase in the overpotential when operated for 50 hours. The overpotential at the end of 50 hours was 222 mV which is even less than the 232 mV measured by the linear sweep voltammetry method. Accordingly, the binder free electrodes fabricated through this method exhibit excellent durability. Therefore, this method of FsLDW produces materials of modest activity and functionality, demonstrating the efficacy of this synthesis process. Furthermore, since the process involves lower quantities of solvents, and uses no heat treatments as used in the conventional processes, the process has a great potential in saving energy and water.

Based on the above method for synthesizing metal oxides and alloys for electrocatalysis using laser, a process involving a single step laser writing on the dried precursor ink on the substrate to produce a variety of metal stated above can be achieved. The process can be used to synthesize patterns of any curvature with minimum feature size of 20 μm. The process allows a variety of products to be synthesized by appropriate changes in the precursor ink.

The application of the above methods can go beyond electrocatalysis. The same method can be used to create micro-patterns of oxides and alloys for interesting applications like sensing, energy storage etc. In some embodiments, the extent of micro-fabrication achievable by this process can be illustrated in FIG. 20. As shown in FIG. 20, concentric squares and circles using femtosecond laser are depicted, and the laser forms crisp patterns with excellent dimensional accuracy. The un-sintered parts can be removed by rinsing in water and ultrasonicating for, e.g., 20 seconds, whereas the sintered parts strongly adhere to the substrate. Further, the concentric circles of three different metals, for example, Ni, Cu, and Ag can be fabricated in three consecutive steps. First, Ag can be deposited using Ag ink, and the un-sintered part can be removed by rinsing in water. Secondly, the Cu ink may be drop cast and the Cu patterning can be formed using laser. The same steps may be repeated for Ni to obtain Ni patterning. The optical microscope images show distinct circles of Ni, Cu and Ag, and the circles of Ni, Cu, and Ag are shown from the EDX line scan in the FESEM image. Accordingly, this fabrication method opens door to the manufacturing of plethora of interesting designs for sensing and energy storage.

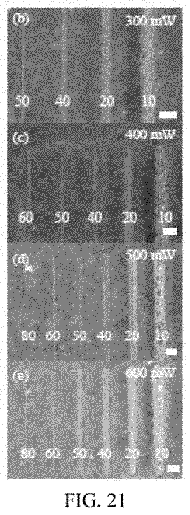

Dimensional accuracy is critical to micro-fabrication. The laser writing speed or the laser power may have an impact on the dimensional accuracy of the laser fabricated lines. For examples, lines with dimension of 50 μm can be fabricated using fs laser. FIG. 21 shows the optical microscope images of the FsLDW patterns. The plot of thickness ratio for various writing speed and laser power reveals the suitable parameters needed to fabricate micropatterns. According to the embodiments of the present disclosure, at the laser writing speed of 50 mm/s-60 mm/s and the laser power of 500 mW-600 mW, micropatterns of the metals can be fabricated with dimensional accuracy.

Therefore, a novel method for in-situ synthesizing and coating high entropy alloy and multi-metal oxide nano-microparticles with one step femtosecond laser direct writing process is provided by the present disclosure. The method can be helpful to fabricate binder free electrodes at room temperature and in open atmosphere. Such process can be rapid and implement extremely low concentration of solvent. The speed of the process can be further improved by using a higher power laser. The femtosecond laser process to synthesize and coat oxides and alloys may be used in the fabrication of sensors, electrodes for energy storage and conversion and many other industrial applications.

The above description of the disclosed embodiments of the present disclosure can enable those skilled in the art to implement or use the present disclosure. Thus, although illustrative example embodiments have been described herein with reference to the accompanying figures, it is to be understood that this description is not limiting and that various other changes and modifications may be affected therein by one skilled in the art without departing from the scope or spirit of the disclosure.

What is claimed is:

1. A method for synthesizing and simultaneously depositing and coating one or more layers of mixed metals to obtain one or more layers of high entropy alloys (HEAs), comprising:
for each layer of HEA,
depositing a first metal precursor ink and drying the first metal precursor ink to obtain a first precursor film layer;
applying a laser-direct writing (LDW) with pulsed laser source to the first precursor film layer to obtain a first layer of HEA, the first layer of HEA having a first metal corresponding to the first metal precursor; and
rinsing the first layer of HEA with water to remove un-sintered precursor film to obtain one or more layers of HEAs, the one or more layers of HEAs including a predetermined pattern of one or more layers, the one or more layers having a single metal or multiple metals.

2. The method according to claim 1, wherein:
when a total number of the one or more layers of metal is 1, a number of HEA is 1; and
when a total number of the one or more layers of metals is equal to or greater than 2, the method further comprising:
depositing a second metal ink on the first layer and drying the second metal ink to obtain a second precursor film layer;
applying the LDW with pulsed laser source to the second precursor film layer; and
repeating the above steps to obtain two or more layers of HEAs, the two or more HEAs including a predetermined pattern of the two or more layers, the two or more layers having multiple metals.

3. The method according to claim 1, wherein the LDW with pulsed laser source is femtosecond laser direct writing (FsLDW) utilizing a femtosecond laser pulse source through a laser direct writing method.

4. The method according to claim 3, further comprising:
forming an FsLDW pattern on a precursor metal film for fabrication.

5. The method according to claim 1, wherein the synthesized product includes nanoparticles in a dimension ranging from 20 nm to 100 nm.

6. The method according to claim 3, wherein parameters of the femtosecond pulse laser include one or more of: a repetition rate, a pulse duration, a predetermined wavelength, a predetermined average power, a predetermined rate, a predetermined pulse width, a number of pulses, an incident fluence, a polarization, an energy intensity, and a lens orientation of a source of the femtosecond pulse laser.

7. The method according to claim 6, wherein a writing condition of repetition rate for the femtosecond pulse laser is 500 kHz, the UV wavelength is 343 nm and a pulse duration is 220 fs.

8. The method according to claim 1, wherein a shape of the single metal or high entropy alloy in a single layer is formed according to a predetermined shape.

9. A material having one or more high entropy alloys (HEAs), comprising:
one or more layers of HEAs including a predetermined pattern of one or more layers, the one or more layers having a single metal or multiple metals,
wherein for each layer of HEA,
a first metal precursor ink is deposited and dried for obtaining a first precursor film layer;
a laser-direct writing (LDW) with pulsed laser source is applied to the first precursor film layer to obtain a first layer of HEA, the first layer of HEA having a first metal corresponding to the first metal precursor; and
the first layer of HEA is rinsed with water to remove un-sintered precursor film to obtain a first layer of HEA.

10. The material according to claim 9, wherein:
when a total number of the one or more layers of metal is 1, a number of HEA is 1; and
when a total number of the one or more layers of metals is equal to or greater than 2, a second metal ink is deposited on the first layer and dried to obtain a second precursor film layer, and the LDW with pulsed laser source is applied to the second precursor film layer, and the above steps are repeated to obtain two or more layers of HEAs, the two or more HEAs including a predetermined pattern of the two or more layers, the two or more layers having multiple metals.

11. The material according to claim 10, wherein the LDW with pulsed laser source is femtosecond laser direct writing (FsLDW).

12. The material according to claim 11, wherein the FsLDW pattern is formed on a substrate for fabrication.

13. The material according to claim 10, wherein the high entropy alloy have nanoparticles in a dimension ranging from 20 nm to 100 nm.

14. The material according to claim 11, wherein parameters of the femtosecond pulse laser include one or more of: a repetition rate, a spectrum of ultraviolet (UV), a pulse duration, a predetermined wavelength, a predetermined average power, a predetermined rate, a predetermined pulse width, a number of pulses, an incident fluence, a polarization, an energy intensity, and a lens orientation of a source of the femtosecond pulse laser.

15. The material according to claim 14, wherein a writing condition of repetition rate for the femtosecond pulse laser is 500 kHz, the UV is 343 nm and a pulse duration is 220 fs.

16. The material according to claim 10, wherein a shape of the high entropy alloy having the multi-layers is formed according to a predetermined shape.
